(19) United States
(12) Patent Application Publication
(10) Pub. No.: US 2025/0279344 A1
(43) Pub. Date: Sep. 4, 2025

(54) PACKAGES WITH ENHANCED HEAT DISSIPATION AND PARASITIC INDUCTANCE MITIGATION

(71) Applicant: TEXAS INSTRUMENTS INCORPORATED, Dallas, TX (US)

(72) Inventors: Woochan KIM, San Jose, CA (US); Anindya PODDAR, Sunnyvale, CA (US); Ashok PRABHU, San Jose, CA (US)

(21) Appl. No.: 18/592,152

(22) Filed: Feb. 29, 2024

(51) Int. Cl. H01L 23/498; H01L 23/00; H01L 23/31; H01L 23/373; H01L 23/48; H01L 23/522

(52) U.S. Cl. CPC H01L 23/49838; H01L 23/3121; H01L 23/373; H01L 23/481; H01L 23/5227; H01L 24/16; H01L 2224/16225; H01L 2924/181

(57) ABSTRACT

In examples, a semiconductor package comprises a semiconductor die having a device side including circuitry and a non-device side opposite the device side; a metal pillar coupled to the device side and extending away from the semiconductor die; and a routing structure coupled to the metal pillar. The routing structure includes first and second metal layers, the first metal layer positioned closer to the device side than the second metal layer and coupled to the second metal layer by way of a via; and a dielectric covering the first and second metal layers and the via. The package includes a die pad coupled to the non-device side of the semiconductor die by way of a thermally conductive material; a die pad extension member coupled to an opposite surface of the die pad than the semiconductor die; and a conductive terminal having a first horizontal member and a second horizontal member coupled to and vertically offset from the first horizontal member, with the second horizontal member soldered to the first metal layer of the routing structure. The package comprises a mold compound covering the semiconductor die, the metal pillar, the routing structure, the die pad, and the conductive terminal, with the first horizontal member and the die pad exposed to an exterior surface of the mold compound.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation. An individual die is then coupled to a die pad and to conductive terminals, sometimes called “leads.” The resulting structure is subsequently covered with a mold compound to produce a package.

### SUMMARY

In examples, a semiconductor package comprises a semiconductor die having a device side including circuitry and a non-device side opposite the device side; a metal pillar coupled to the device side and extending away from the semiconductor die; and a routing structure coupled to the metal pillar. The routing structure includes first and second metal layers, the first metal layer positioned closer to the device side than the second metal layer and coupled to the second metal layer by way of a via; and a dielectric covering the first and second metal layers and the via. The package includes a die pad coupled to the non-device side of the semiconductor die by way of a thermally conductive material; a die pad extension member coupled to an opposite surface of the die pad than the semiconductor die; and a conductive terminal having a first horizontal member and a second horizontal member coupled to and vertically offset from the first horizontal member, with the second horizontal member soldered to the first metal layer of the routing structure. The package comprises a mold compound covering the semiconductor die, the metal pillar, the routing structure, the die pad, and the conductive terminal, with the first horizontal member and the die pad exposed to an exterior surface of the mold compound.

In examples, a method for manufacturing a package comprises coupling a metal pillar extending from a device side of a semiconductor die to a routing structure, with the device side having circuitry formed therein, the routing structure comprising first and second metal layers, the first metal layer positioned closer to the device side than the second metal layer and coupled to the second metal layer by way of a via, and a dielectric covering the first and second metal layers and the via. The method comprises coupling a non-device side of the semiconductor die opposing the device side of the semiconductor die to a die pad by a thermally conductive material; coupling a conductive terminal to the routing structure; and covering the semiconductor die, the die pad, the metal pillar, the routing structure, and the conductive terminal with a mold compound, with the conductive terminal exposed to an exterior surface of the mold compound.

### BRIEF DESCRIPTION OF THE DRAWINGS

FIG. 1 is a flow diagram of a method for manufacturing a semiconductor package, in accordance with various examples.

FIGS. 2A1, 2A2, 2A3, 2A4, and 2A5 are profile, alternative profile, top-down, bottom-up, and perspective views, respectively, of a routing structure and a semiconductor die, in accordance with various examples.

FIGS. 2B1, 2B2, 2B3, 2B4, and 2B5 are profile, alternative profile, top-down, bottom-up, and perspective views, respectively, of a die pad, die pad extension member, and conductive terminals, in accordance with various examples.

FIGS. 2C1, 2C2, 2C3, 2C4, and 2C5 are profile, alternative profile, top-down, bottom-up, and perspective views, respectively, of a routing structure and semiconductor die coupled to a die pad, a die pad extension member, and conductive terminals, in accordance with various examples.

FIGS. 2D1, 2D2, 2D3, 2D4, and 2D5 are profile, alternative profile, top-down, bottom-up, and perspective views of a semiconductor package with enhanced heat dissipation and parasitic inductance mitigation, in accordance with various examples.

FIGS. 2E1 and 2E2 are profile and perspective views of a routing structure and semiconductor die coupled to a die pad, a die pad extension member, and conductive terminals, in accordance with various examples.

FIG. 2F is a profile, cross-sectional view of a routing structure in accordance with various examples.

FIGS. 3A1, 3A2, 3A3, 3A4, and 3A5 are profile, alternative profile, top-down, bottom-up, and perspective views, respectively, of a routing structure and a semiconductor die, in accordance with various examples.

FIGS. 3B1, 3B2, 3B3, 3B4, and 3B5 are profile, alternative profile, top-down, bottom-up, and perspective views, respectively, of a die pad, die pad extension member, and conductive terminals, in accordance with various examples.

FIGS. 3C1, 3C2, 3C3, 3C4, and 3C5 are profile, alternative profile, top-down, bottom-up, and perspective views, respectively, of a routing structure and semiconductor die coupled to a die pad, a die pad extension member, and conductive terminals, in accordance with various examples.

FIGS. 3D1, 3D2, 3D3, 3D4, and 3D5 are profile, alternative profile, top-down, bottom-up, and perspective views of a semiconductor package with enhanced heat dissipation and parasitic inductance mitigation, in accordance with various examples.

FIGS. 3E1 and 3E2 are profile and perspective views of a routing structure and semiconductor die coupled to a die pad, a die pad extension member, and conductive terminals, in accordance with various examples.

FIG. 3F is a profile, cross-sectional view of a routing structure in accordance with various examples.

FIG. 4 is a block diagram of an electronic device comprising a semiconductor package with enhanced heat dissipation and parasitic inductance mitigation, in accordance with various examples.

### DETAILED DESCRIPTION

Heat dissipation is a recurring technical challenge in the semiconductor packaging industry. Different solutions have been employed to varying effect. In some cases, a “flip-chip” semiconductor die is oriented such that a device side in which circuitry is formed is oriented downward, facing a die pad or other part of a lead frame, and non-bond wire structures such as pillars and bumps are used to couple the device side to the die pad or lead frame. A metal lid is coupled to the back side of the semiconductor die (also referred to as the non-device side of the semiconductor die), and the metal lid is exposed to an exterior surface of the package. In this way, heat is dissipated through the non-device side of the die, the metal lid, and out of the package. While some heat may be dissipated in this manner, the package is coupled to a printed circuit board (PCB), and heat dissipation through the PCB is suboptimal because of the limited contact area between the device side of the semiconductor die and the die pad (i.e., through pillars or bumps). Further, even the heat dissipated through the metal lid is suboptimal because the thermal pad positioned between the metal lid and the non-device side of the semiconductor die is relatively small, thus restricting the amount of heat that can be dissipated through the metal lid. In other cases, the semiconductor die does not have a “flip-chip” configuration, meaning that the non-device side of the semiconductor die is facing downward and is coupled to the die pad, while the device side of the semiconductor die is facing upward and is coupled to conductive terminals (or “leads”) through bond wires. While thermal dissipation through the die pad and the PCB to which the package is coupled may be improved relative to other solutions, the bond wires introduce parasitic inductance into the package. Parasitic inductance in a package can present numerous technical challenges, especially at high frequency of operation, thereby effectively limiting the frequencies of operation that can be achieved. Examples of such technical challenges associated with parasitic inductance can include problems with signal integrity, power supply noise, electromagnetic interference (EMI), switching losses, resonance effects, and heat dissipation challenges, depending on the application.

This disclosure describes various examples of a package that provides enhanced heat dissipation and parasitic inductance mitigation, thereby resolving the numerous technical challenges described above. In examples, a package includes a semiconductor die having a device side including circuitry and a non-device side opposite the device side. The package includes a metal pillar coupled to the device side and extending away from the semiconductor die. The package includes a routing structure coupled to the metal pillar, with the routing structure including first and second metal layers. The first metal layer is positioned closer to the device side than the second metal layer and is coupled to the second metal layer by way of a via. The routing structure also includes a dielectric covering the first and second metal layers and the via. The package includes a thermally conductive die pad coupled to the non-device side of the semiconductor die by way of a thermally conductive material. The package also includes a conductive terminal having a first horizontal member and a second horizontal member coupled to and vertically offset from the first horizontal member, the second horizontal member soldered to the first metal layer of the routing structure. Further, the package includes a mold compound covering the semiconductor die, the metal pillar, the routing structure, the thermally conductive die pad, and the conductive terminal, with the first horizontal member and the die pad exposed to an exterior surface of the mold compound.

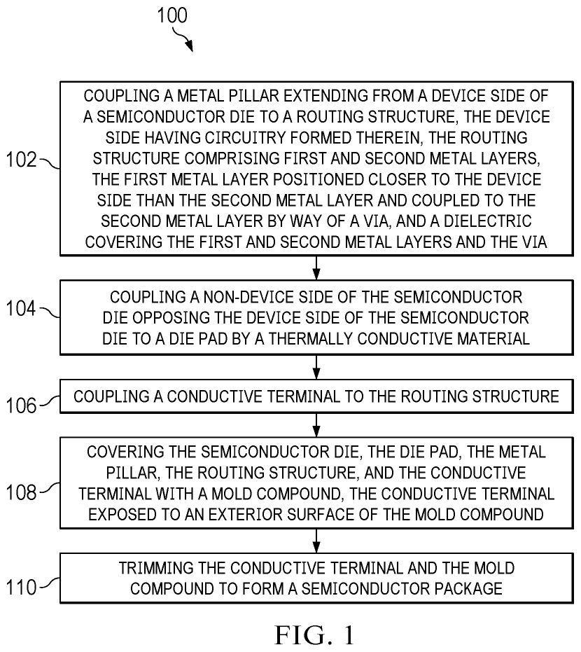

FIG. 1 is a flow diagram of a method 100 for manufacturing a semiconductor package, in accordance with various examples. The method 100 includes coupling a metal pillar extending from a device side of a semiconductor die to a routing structure (102). The device side has circuitry formed therein (102). The routing structure comprises first and second metal layers (102). The first metal layer is positioned closer to the device side than the second metal layer and is coupled to the second metal layer by way of a via (102). A dielectric covers the first and second metal layers and the via (102).

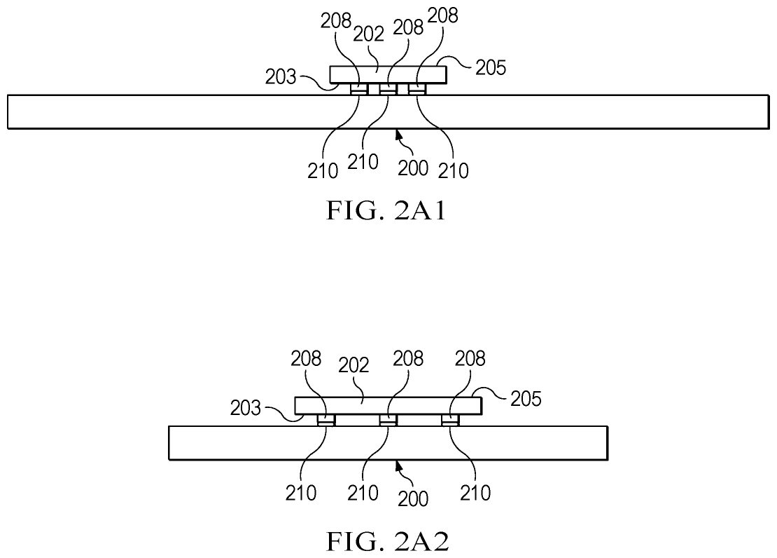

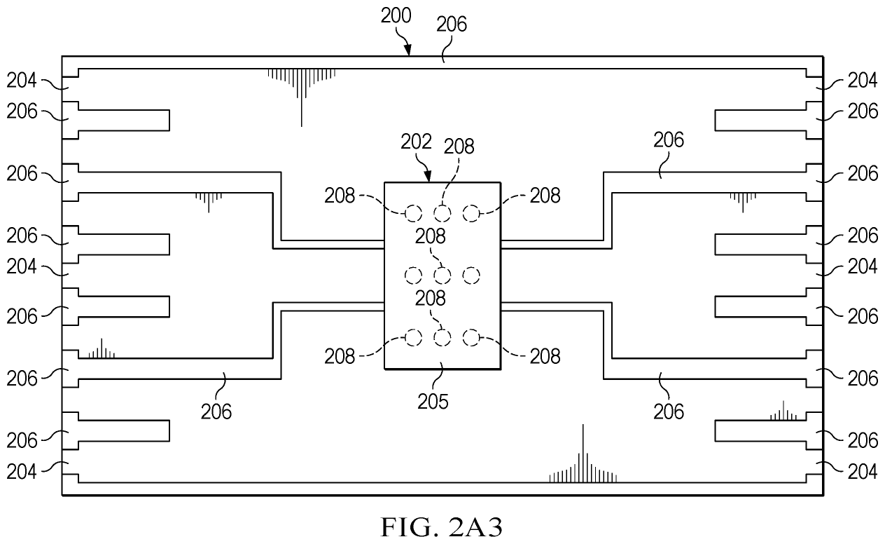

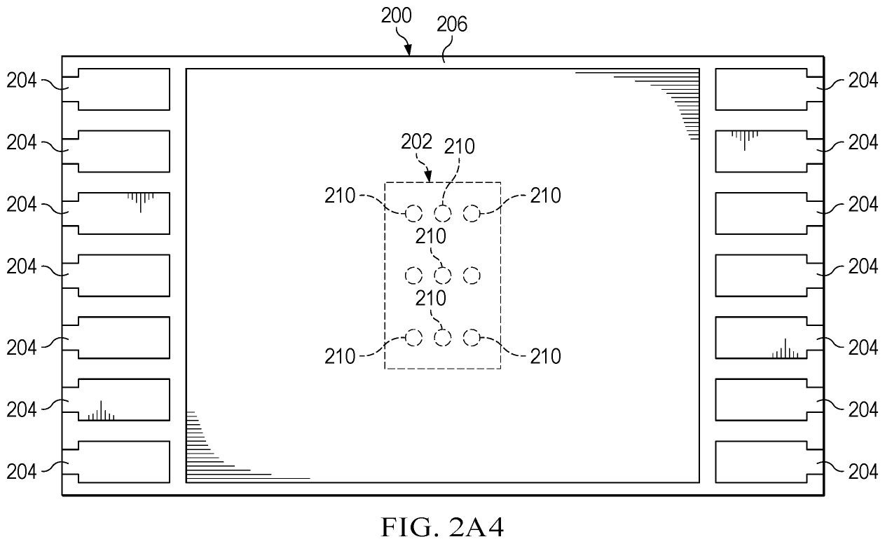

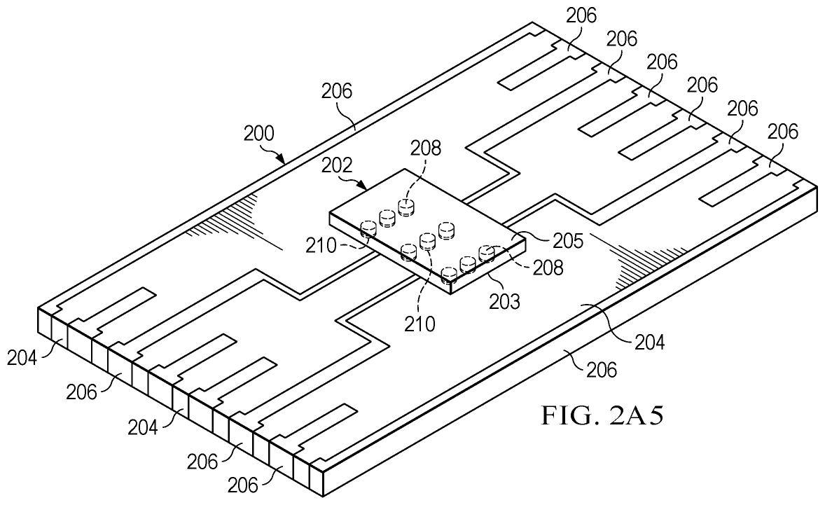

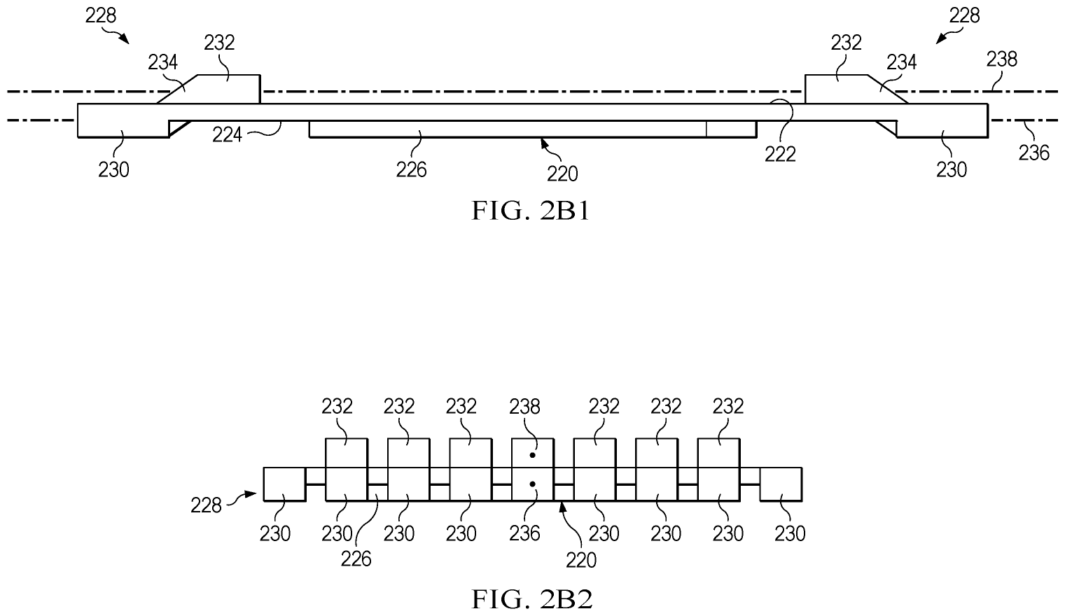

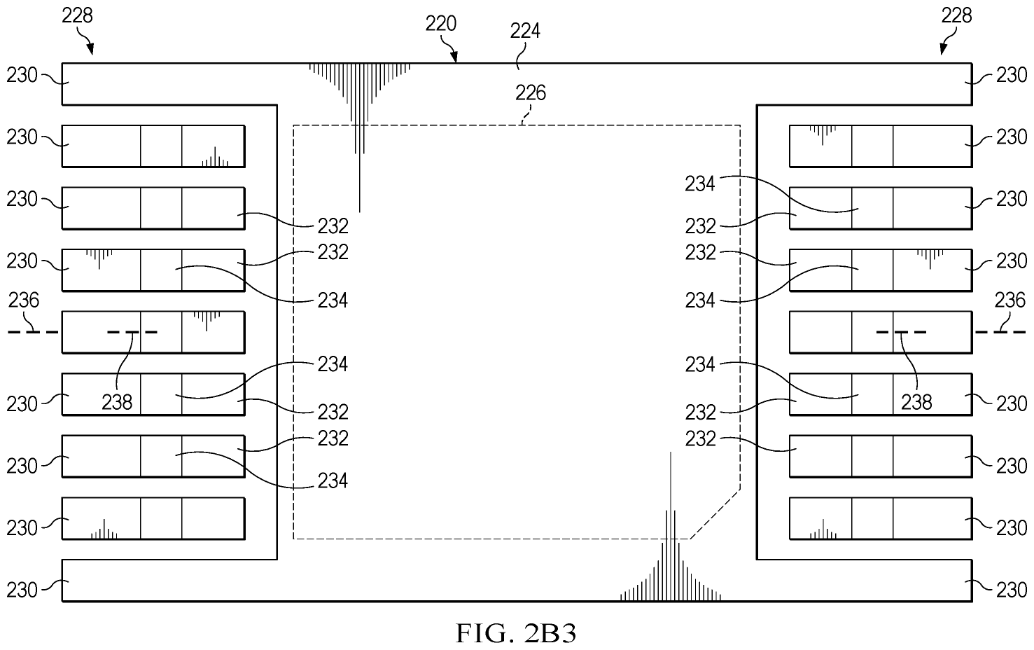

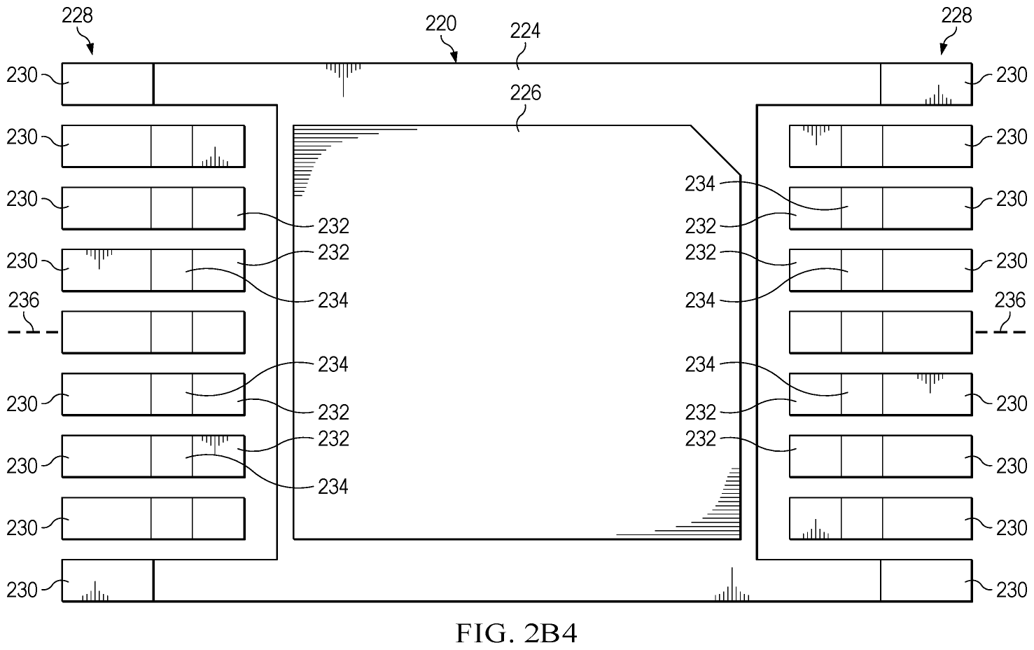

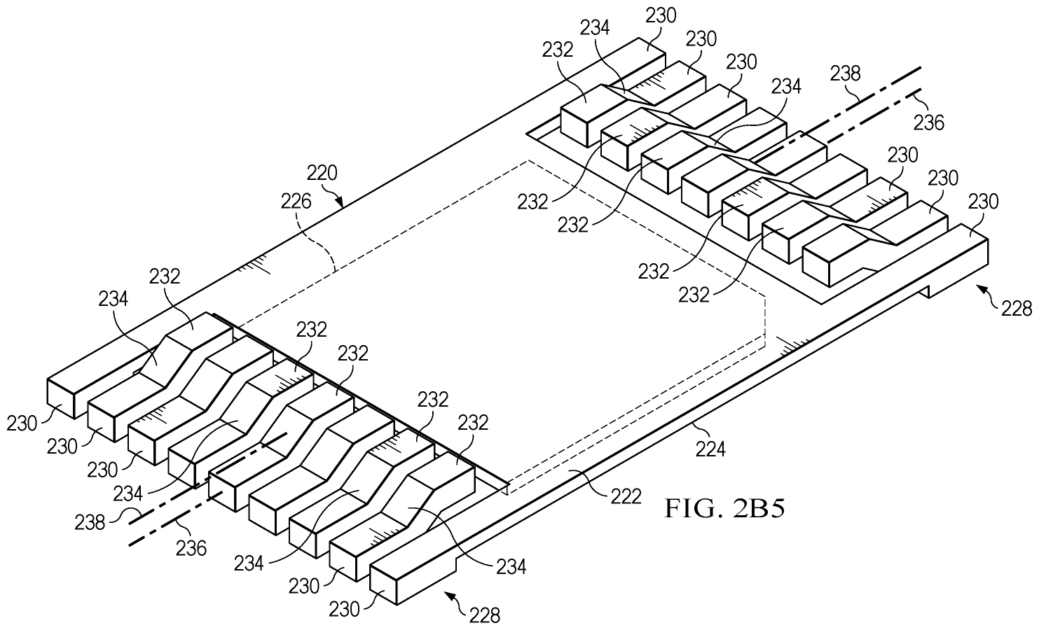

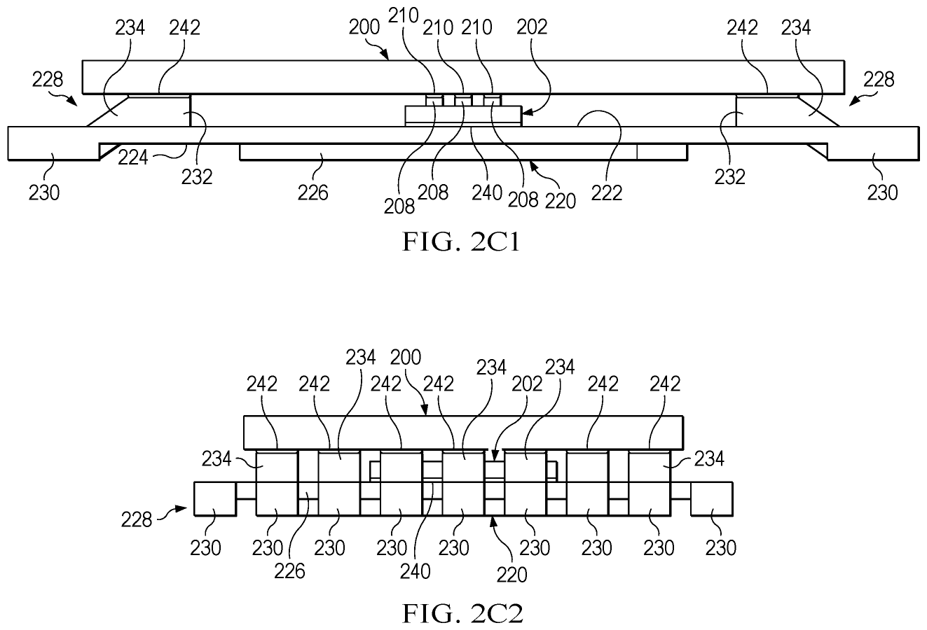

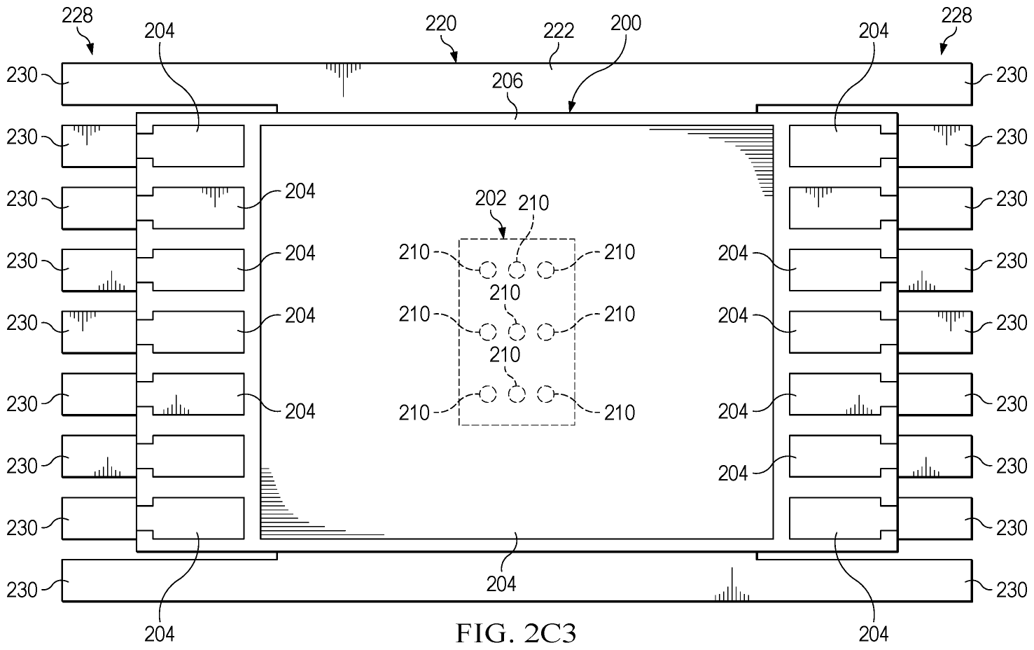

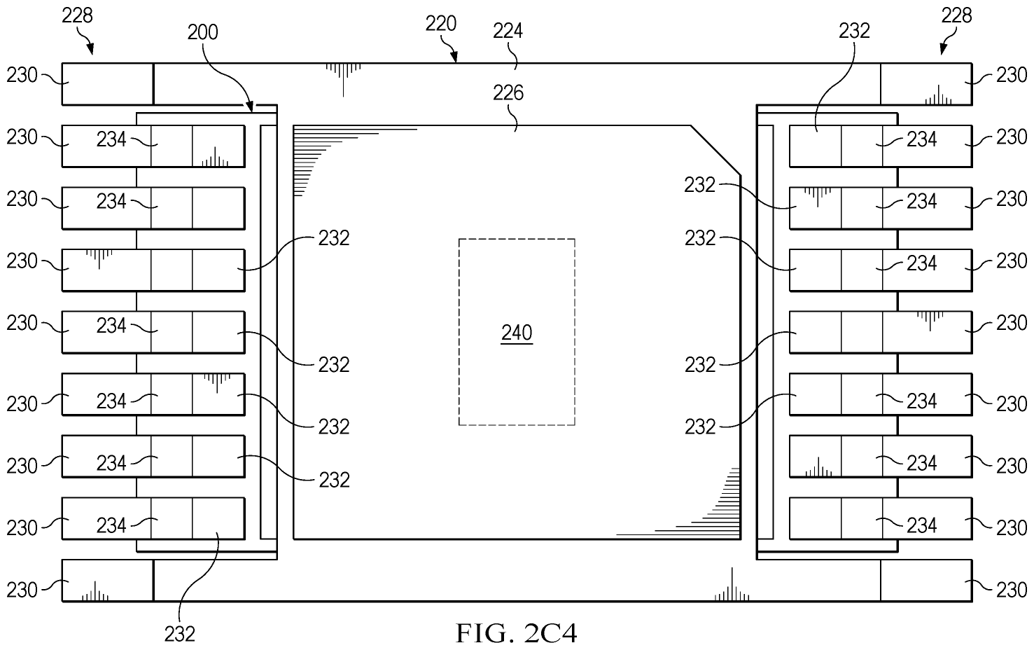

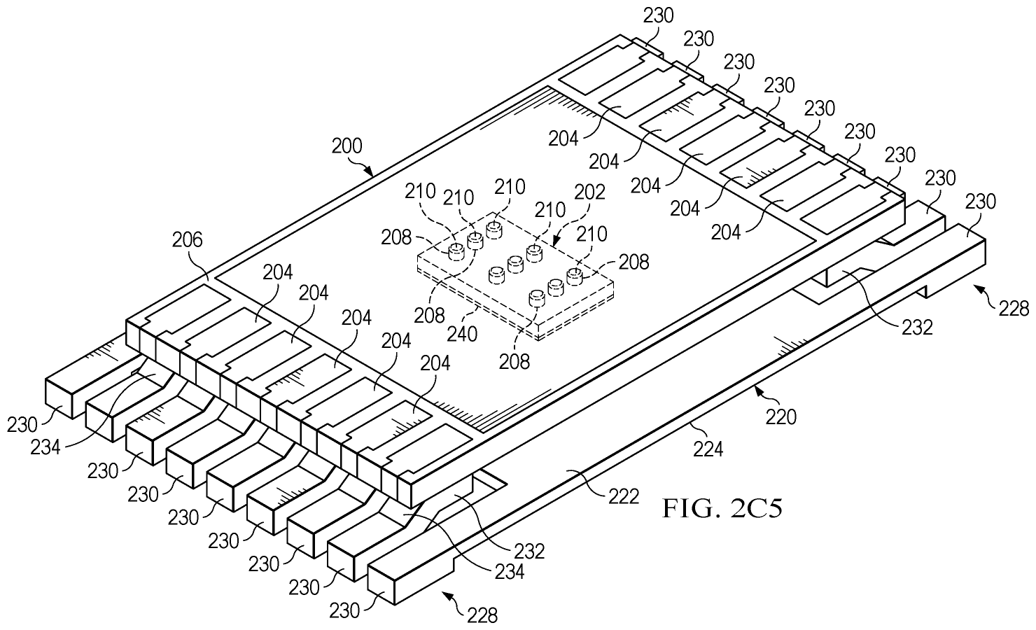

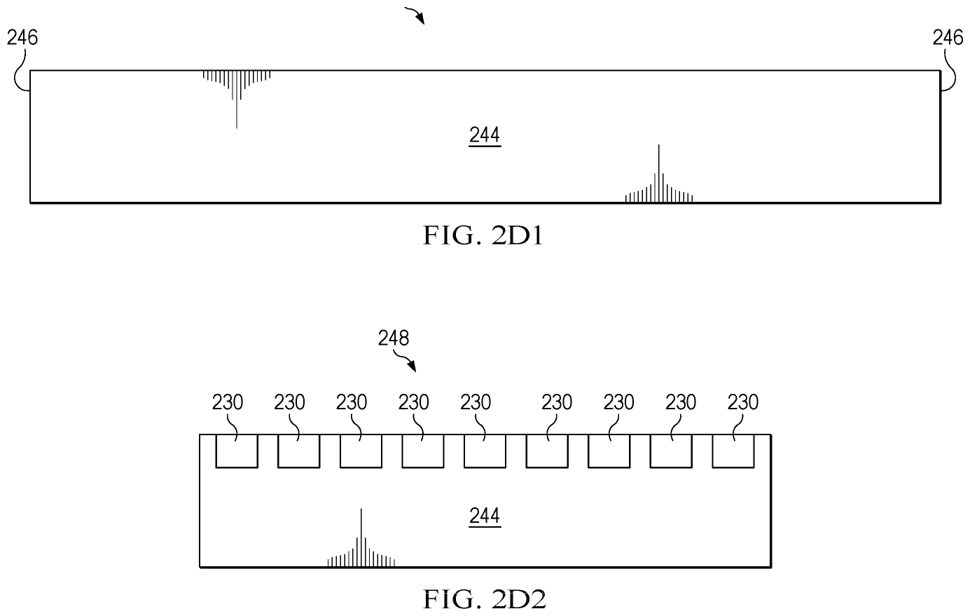

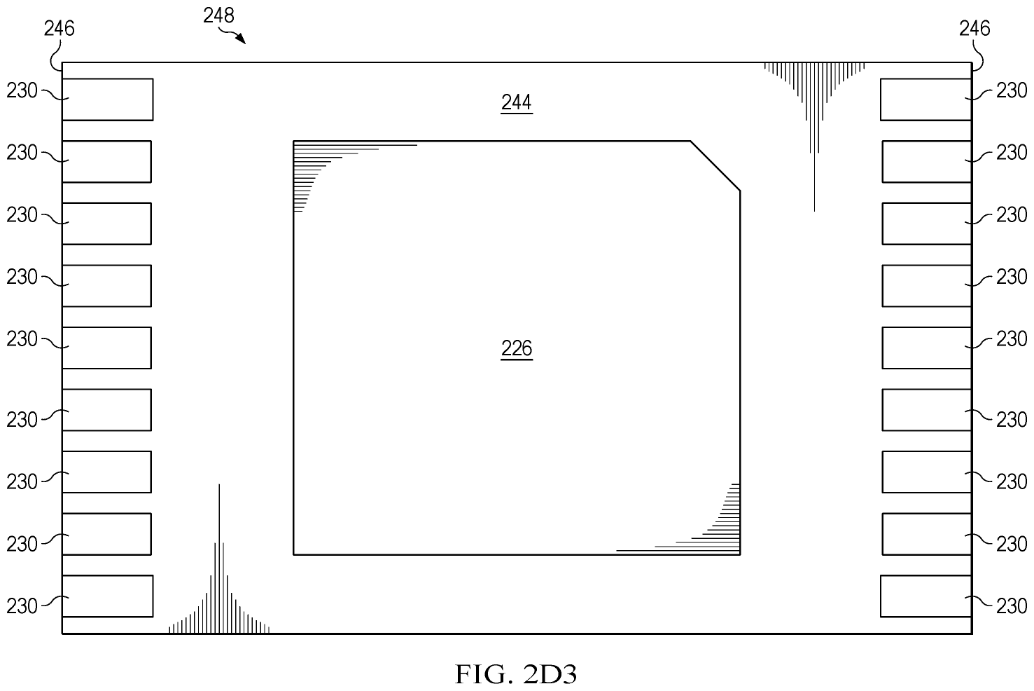

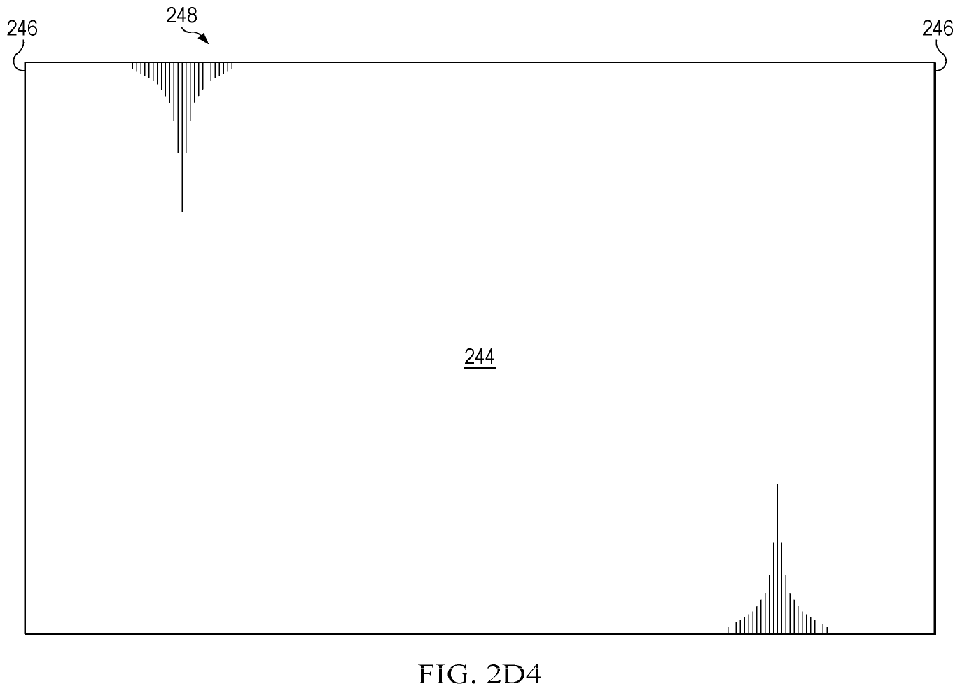

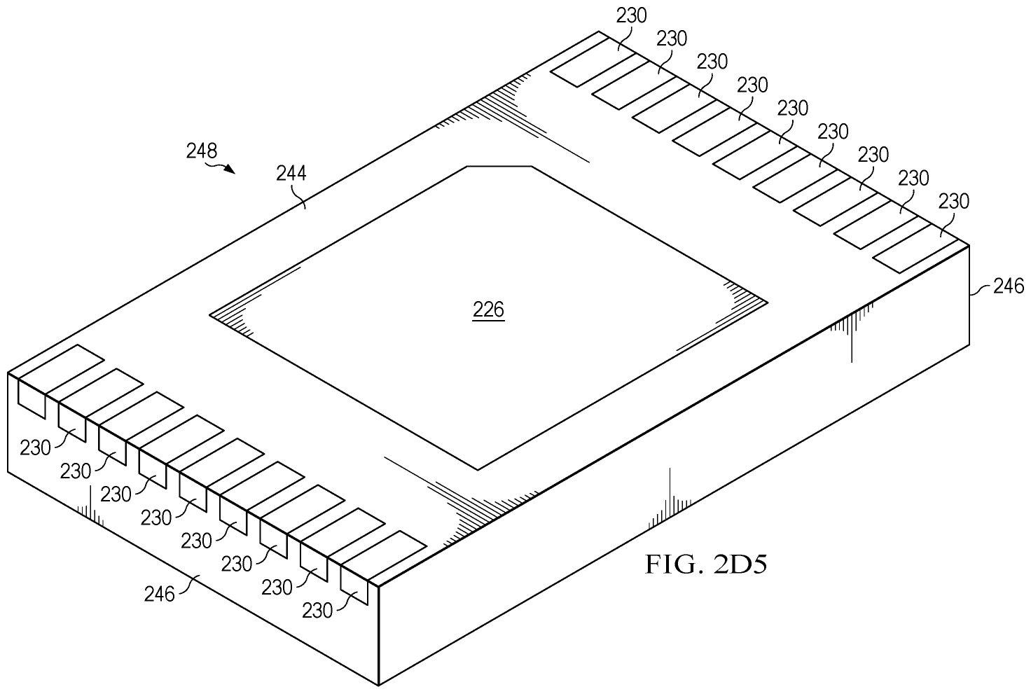

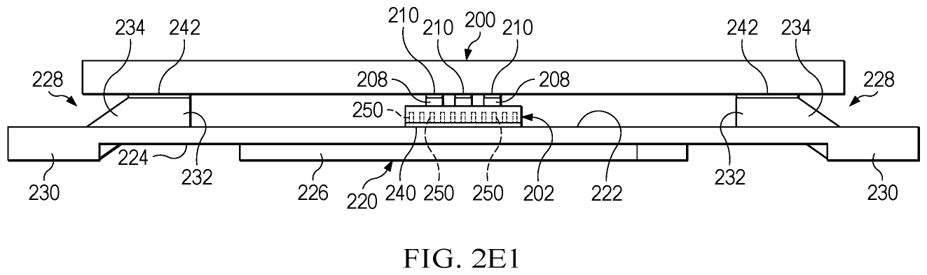

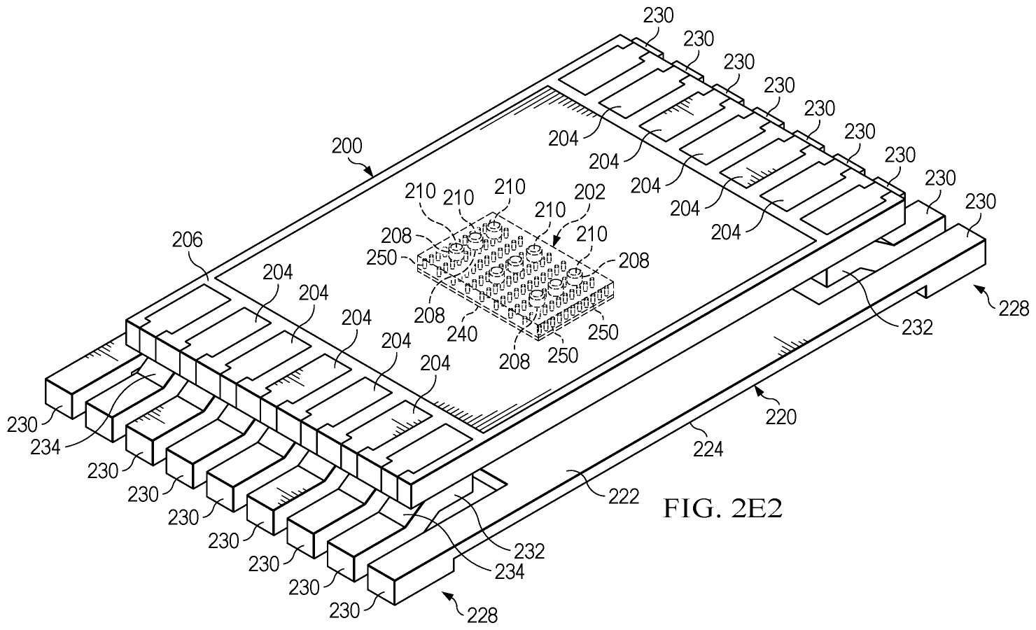

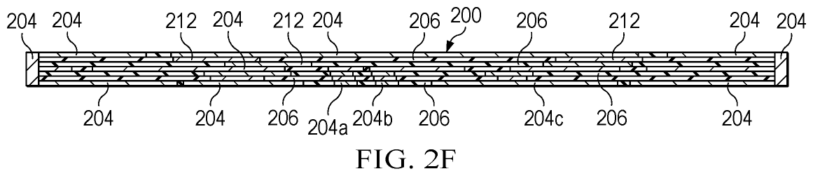

FIGS. 2A1, 2A2, 2A3, 2A4, and 2A5 are profile, alternative profile, top-down, bottom-up, and perspective views, respectively, of an example routing structure 200 and an example semiconductor die 202 coupled to the routing structure 200, in accordance with various examples. In examples, the semiconductor die 202 is a gallium nitride (GaN) die, although in other examples, other types of semiconductor materials, such as silicon (Si) or silicon carbide (SiC), may be useful. Further, the circuitry formed in the semiconductor die 202 may include radio frequency (RF) circuitry configured to perform one or more RF operations in an RF application, although the scope of this disclosure is not limited to semiconductor dies that perform RF operations. The principles described herein may be extended to any suitable type of application. The semiconductor die 202 includes a device side 203 in which the circuitry of the semiconductor die 202 is formed, and the semiconductor die 202 also includes a non-device side 205 opposing the device side 203.

The routing structure 200 is a multi-layered routing device. The routing structure includes multiple metal layers 204 that are separated from each other by dielectric layers 206. Metal layers 204 and dielectric layers 206 may be co-located in the same layer, or horizontal plane, of the routing structure 200. Each of the metal layers 204 may be coupled to another one or more of the metal layers 204 by way of one or more metal vias, thus forming a network of metal layers to carry electrical signals.

The routing structure 200 is not a printed circuit board (PCB). Unlike a PCB, which typically has metal layers that are separated by air, the dielectric layers 206 of the routing structure 200 are solid and tangible (i.e., not air), such as AJINOMOTO® build-up film (ABF). Furthermore, unlike a PCB, the routing structure 200 is located inside a semiconductor package. PCBs, by contrast, are coupled to and external to semiconductor packages.

Accordingly, a routing structure is expressly defined herein as a non-PCB structure having a network of two or more metal layers and vias connecting the metal layers, and a solid, tangible, non-gaseous dielectric in contact with the metal layers.

Referring briefly to FIG. 2F, which provides a profile, cross-sectional view of the routing structure 200, the routing structure 200 includes metal layers 204 and dielectric layers 206, as described above. Vias 212 couple metal layers 204 to each other, thereby forming the above-described network of metal layers 204. The specific spatial patterns of the metal layers 204 may vary depending on design needs and the particular application in which the routing structure 200 is being deployed. The dielectric layers 206 may comprise a solid, tangible dielectric, such as, for example, ABF, but the dielectric layers 206 do not include air or any other gaseous dielectric. The metal layers 204 include metal members 204a, 204b, and 204c, each of which may couple to a different one of metal pillars 208.

The routing structure 200 may be formed by using an iterative process in which a layer of metal is plated, a dielectric layer is applied, and a grinding process is performed to reduce the thickness of the dielectric layer and/or the metal layer and to achieve a top surface of the dielectric layer through which areas of the metal layer are exposed. The process then begins again, until a routing structure with the desired architecture is obtained.

Metal pillars 208 extend from the device side 203 of the semiconductor die 202. The metal pillars 208 are coupled to the circuitry formed in the device side 203 and extend away from the device side 203, toward the routing structure 200. The metal pillars 208 are coupled to the routing structure 200, and more specifically, to the network of metal layers 204 (e.g., metal members 204a, 204b, and 204c, and possibly other metal members not visible in the cross-sectional view of FIG. 2F), by any suitable, conductive adhesive, such as solder bumps 210.

Referring again to FIG. 1, the method 100 includes coupling a non-device side of the semiconductor die opposing the device side of the semiconductor die to a die pad by a thermally conductive material (104).

FIGS. 2B1, 2B2, 2B3, 2B4, and 2B5 are profile, alternative profile, top-down, bottom-up, and perspective views, respectively, of a die pad, die pad extension member, and conductive terminals, in accordance with various examples. In particular, FIGS. 2B1-2B5 show a die pad 220 having a surface 222 and a surface 224 opposite the surface 222, a die pad extension member 226 coupled to the surface 224 and extending away from the surface 224, and conductive terminals 228. At least one of the conductive terminals 228 includes a first horizontal member 230, a second horizontal member 232, and a connecting member 234 coupling the first and second horizontal members 230, 232 to each other. The first and second horizontal members 230, 232 are vertically offset from each other, meaning that an axial center 236 of the first horizontal member 230 and an axial center 238 of the second horizontal member 232 are vertically distanced from each other. Furthermore, the second horizontal member 232 is more proximal to the die pad 220 than is the first horizontal member 230, and the first horizontal member 230 is more distal to the die pad 220 than is the second horizontal member 232.

The connecting member 234 extends from the first horizontal member 230 to the second horizontal member 232 at an angle relative to the horizontal plane in which the axial center 236 lies. In examples, this angle ranges between 30 degrees and 60 degrees, with a larger (i.e., steeper) angle being disadvantageous because it unnecessarily increases the clearance between the routing structure 200 and the die pad 220, in addition to requiring a thicker semiconductor die 202 and/or longer metal pillars 208, and with a smaller (i.e., shallower) angle being disadvantageous because it may leave inadequate clearance between the routing structure 200 and the die pad 220 for the semiconductor die 202 and the metal pillars 208.

As described below, upon application of a mold compound, the die pad extension member 226 is exposed to an exterior surface (i.e., bottom surface) of the mold compound. This exposure facilitates heat dissipation away from the semiconductor die 202 and out of the semiconductor package. Thus, the thickness of the die pad extension member 226 must be such that it extends from the surface 224 to the bottom surface of the mold compound (i.e., the bottom surface of the semiconductor package). The combined thickness of the die pad extension member 226 and the die pad 220 is approximately equal to the thickness of the first horizontal member 230, as shown. The die pad extension member 226 may be part of the die pad 220 (i.e., the die pad 220 and the die pad extension member 226 are a monolithic unit), or the die pad extension member 226 may be coupled to the die pad 220 using any suitable adhesive.

FIGS. 2C1, 2C2, 2C3, 2C4, and 2C5 are profile, alternative profile, top-down, bottom-up, and perspective views, respectively, of a routing structure and semiconductor die coupled to a die pad, a die pad extension member, and conductive terminals, in accordance with various examples. More specifically, FIGS. 2C1-2C5 depict the structure of FIGS. 2A1-2A5 being coupled to the structure of FIGS. 2B1-2B5. In examples, the non-device side 205 of the semiconductor die 202 is coupled to the surface 222 of the die pad 220 using a suitable adhesive, such as a suitable die attach material. As shown in FIGS. 2C1-2C5, die attach material 240 couples the semiconductor die 202 to the surface 222 of the die pad 220. The die attach material 240 (examples of which include, e.g., solder and silver epoxy) is thermally conductive so that it can facilitate the transmission of heat from the semiconductor die 202 to the die pad extension member 226 via the die pad 220, thereby efficiently removing heat from the semiconductor die 202 and from the semiconductor package more generally. The metal pillars 208 extending from the semiconductor die 202 are coupled to the routing structure 200 by way of solder bumps 210. Any suitable number of metal pillars 208 may be included.

The method 100 also includes coupling a conductive terminal to the routing structure (106). As FIGS. 2C1-2C5 show, an adhesive, such as solder 242, couples the conductive terminals 228 (e.g., the second horizontal members 232) to the routing structure 200 (e.g., to one or more of the metal layers 204).

As shown, the second horizontal member 232 of the conductive terminal 228 is closer to the routing structure 200 than is the surface 222 of the die pad 220 to which the semiconductor die 202 is coupled

In examples, the semiconductor die 202 has a thickness ranging between 50 microns and 250 microns, and in those specific examples, it is critical that the thickness of the die pad 220 range between 50 microns and 500 microns. In these specific examples, a thickness of the die pad 220 above this range is disadvantageous because it introduces an unacceptable degree of mechanical stress to the die 202 and unacceptably increase material costs, and a thickness of the die pad 220 below this range is disadvantageous because the die pad 220 will not adequately spread heat.

The method 100 further includes covering the semiconductor die, the die pad, the metal pillar, the routing structure, and the conductive terminal with a mold compound, the conductive terminal exposed to an exterior surface of the mold compound (108), and trimming the conductive terminal and the mold compound to form a semiconductor package (110). FIGS. 2D1, 2D2, 2D3, 2D4, and 2D5 are profile, alternative profile, top-down, bottom-up, and perspective views of a semiconductor package with enhanced heat dissipation and parasitic inductance mitigation, in accordance with various examples. More specifically, FIGS. 2D1-2D5 show a mold compound 244 covering the structure shown in FIGS. 2C1-2C5. The die pad extension member 226 is exposed to the bottom surface of the mold compound 244, as are the first horizontal members 230 of the conductive terminals 228. The first horizontal members 230 of the conductive terminals 228 may also be exposed to side surfaces 246 of the mold compound 244, such as to facilitate solder wetting.

Although the structure of FIGS. 2B1-2B5 is depicted as being a standalone structure, in practice, multiple such structures may be coupled to each other in a lead frame format. Tie bars, dam bars, and other such structures may be included to provide mechanical support, physical connections, control of mold compound flow, etc. After the mold compound 244 is applied, various portions of the lead frame may be trimmed, e.g., the conductive terminals 228, tie bars, dam bars, and/or a mold compound strip covering multiple instances of the structure shown in FIGS. 2C1-2C5. Such trimming produces a standalone semiconductor package 248, as FIGS. 2D1-2D5 show.

As described above, the thermally conductive die attach material 240 and the die pad extension member 226 transmit heat away from the semiconductor die 202 and out of the semiconductor package 248. To further facilitate this heat dissipation, through-silicon vias may be formed inside the semiconductor die 202. FIGS. 2E1 and 2E2 are profile and perspective views of a routing structure and semiconductor die coupled to a die pad, a die pad extension member, and conductive terminals, in accordance with various examples. More particularly, FIGS. 2E1 and 2E2 show through-silicon vias 250 extending through at least a portion of the thickness of the semiconductor die 202 and extending to the non-device side 205 of the semiconductor die 202. By extending to the non-device side 205 and being exposed to an exterior of the semiconductor die 202 at the non-device side 205, the through-silicon vias 250 make contact with the thermally conductive die attach material 240, thereby efficiently collecting and transferring heat away from the circuitry of the semiconductor die 202, through the die attach material 240, through the die pad 220 and the die pad extension member 226, and out of the semiconductor package 248. In examples containing such through-silicon vias 250, the distance between the circuitry formed in the device side 203 of the semiconductor die 202 and the ends of the through-silicon vias 250 most proximal to the device side 203 ranges between 5 microns and 20 microns, with a distance above this range being disadvantageous because of the lack of a robust heat dissipation pathway, and with a distance below this range being disadvantageous because it can result in brittleness of the die 202. Further, although the vias 250 are referred to herein as through-silicon vias, the vias 250 also may extend through other types of semiconductor material.

Referring to FIGS. 2A1-2F, in operation, signals generated by the semiconductor die 202 are carried to the metal layers 204 through the metal pillars 208. The metal layers 204 and/or the vias 212 provide the signals to the second horizontal members 232, which provide the signals to the first horizontal members 230 via the connecting members 234. The first horizontal members 230 provide the signals to a PCB to which the semiconductor package 248 is coupled. Signals may be provided from the PCB to the semiconductor die 202 by the same electrical pathway.

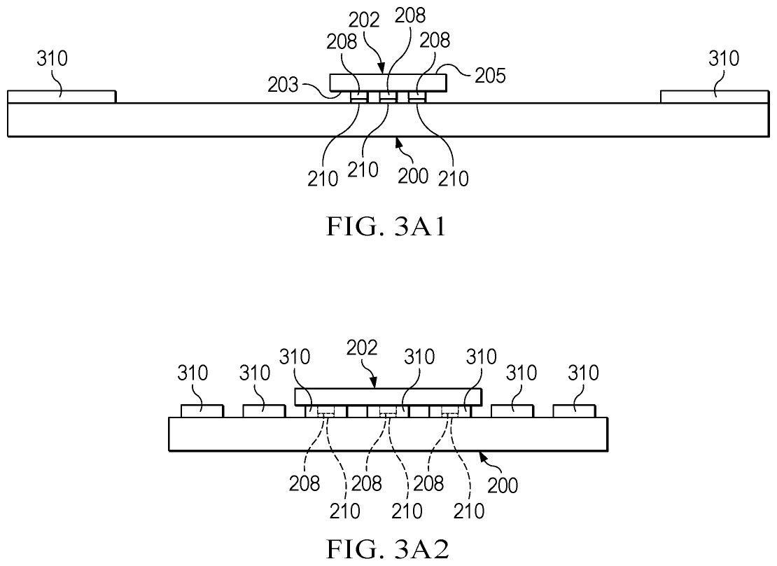

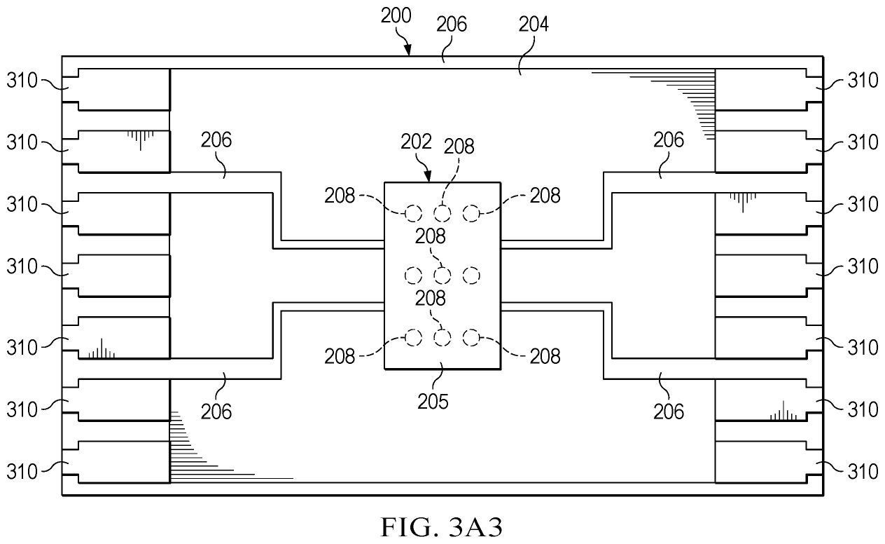

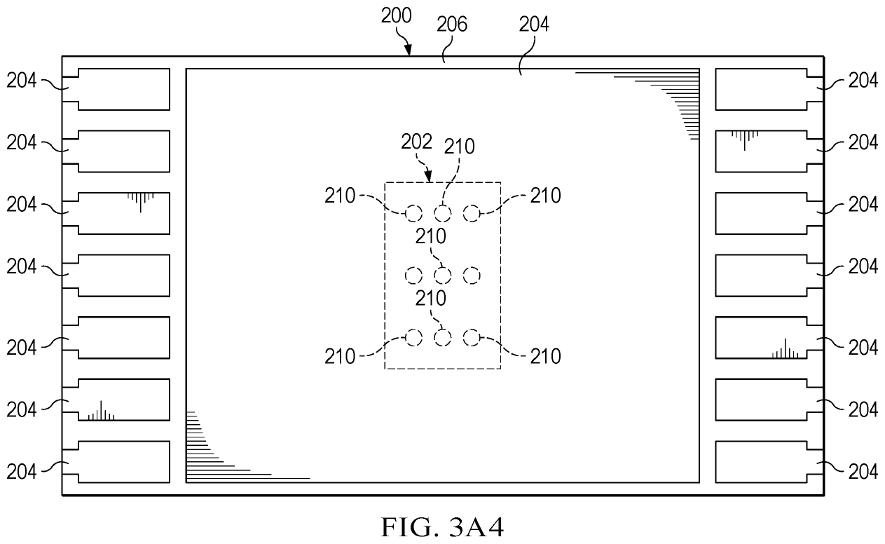

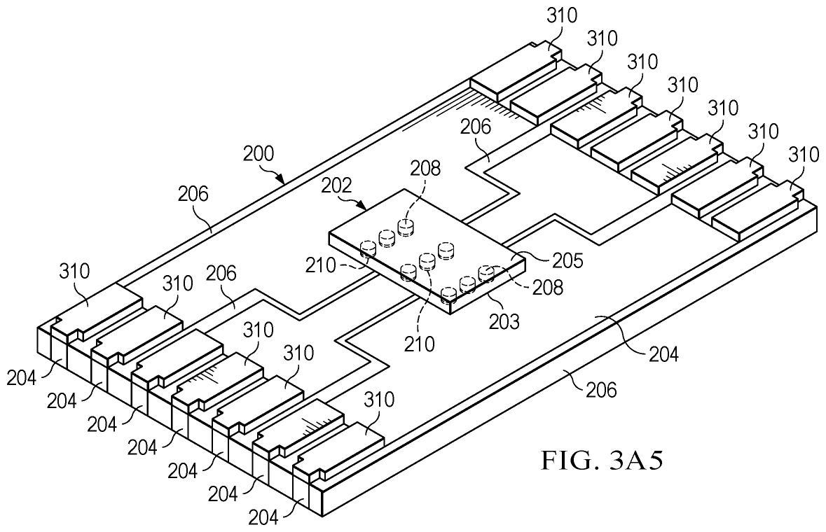

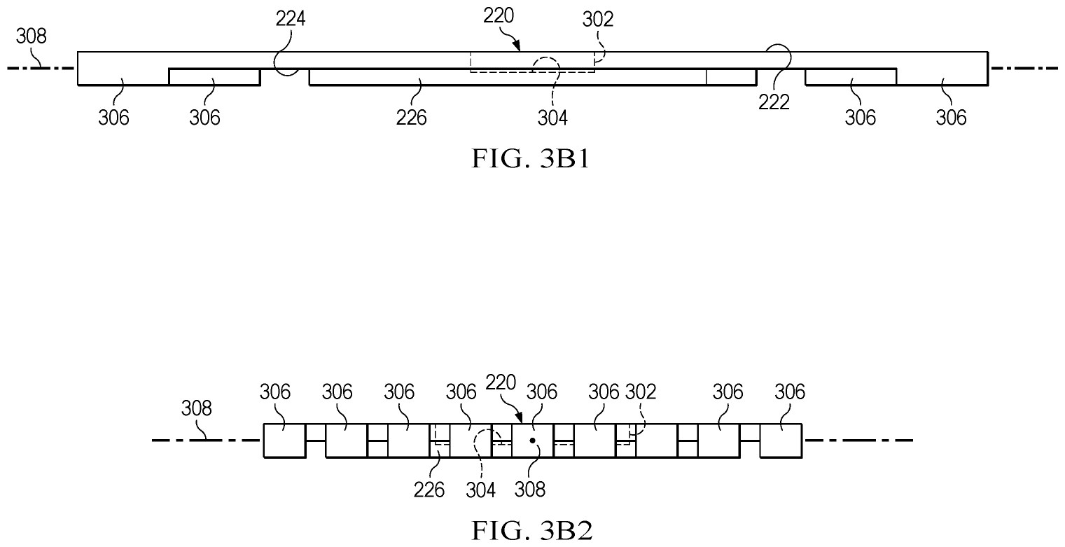

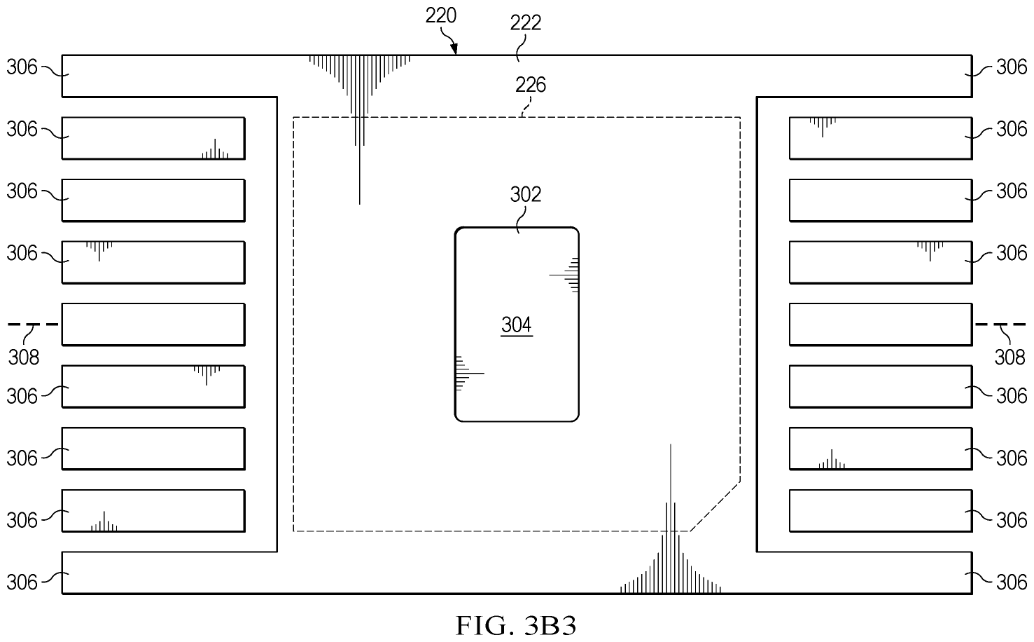

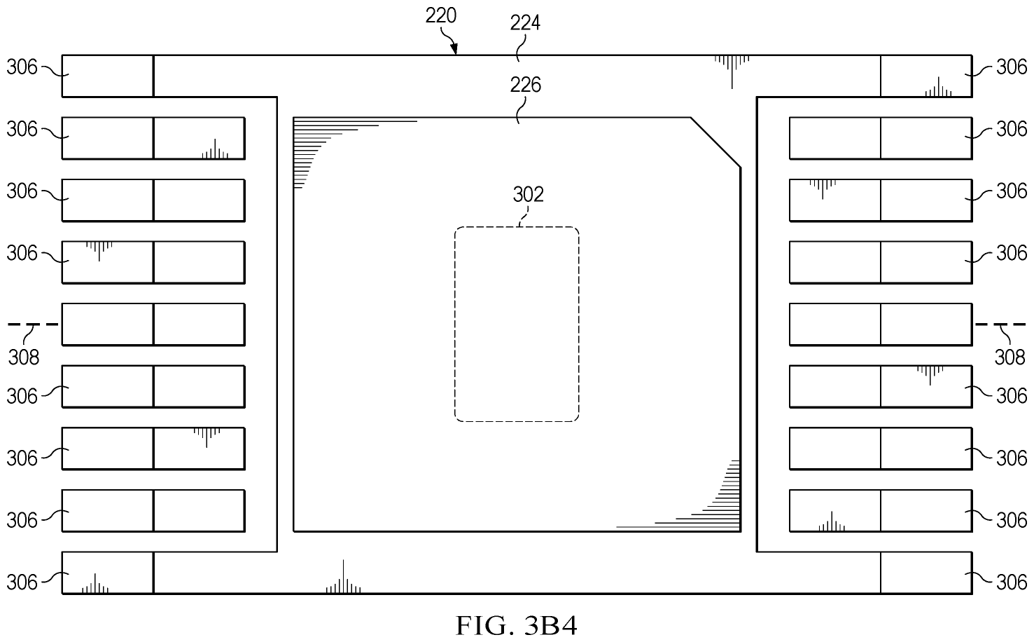

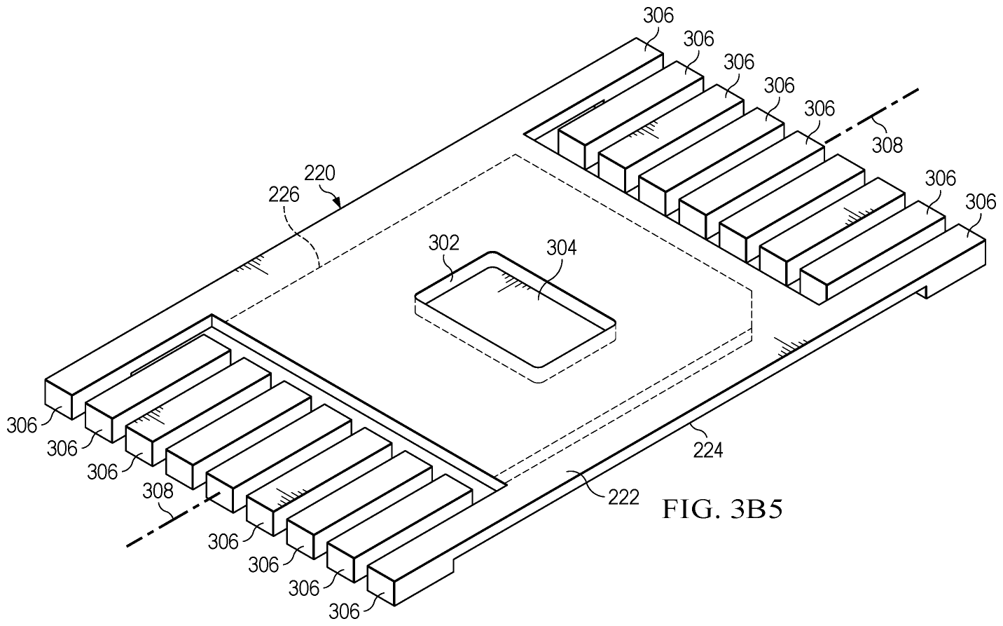

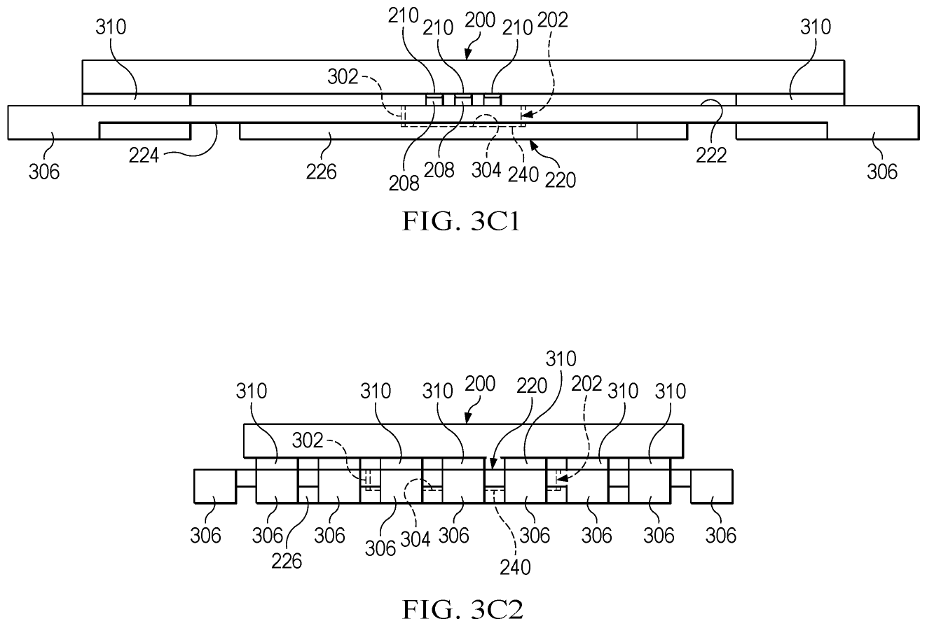

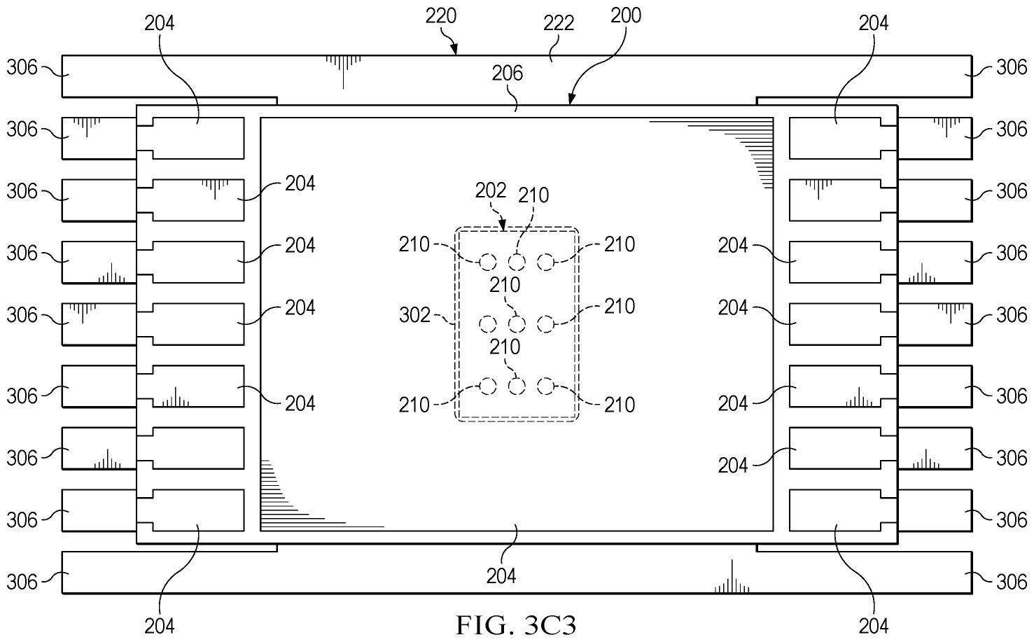

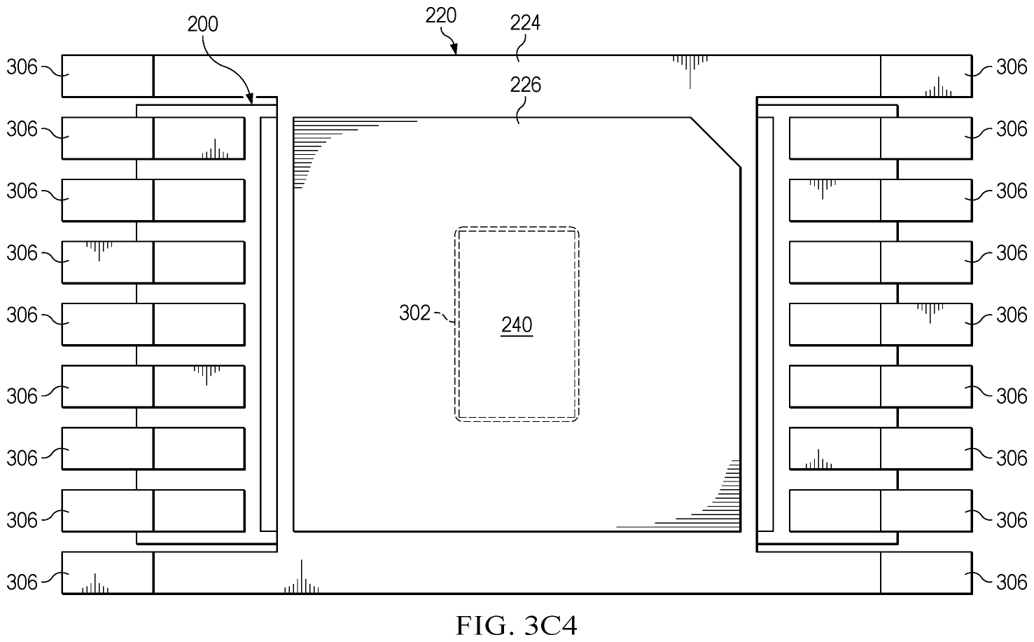

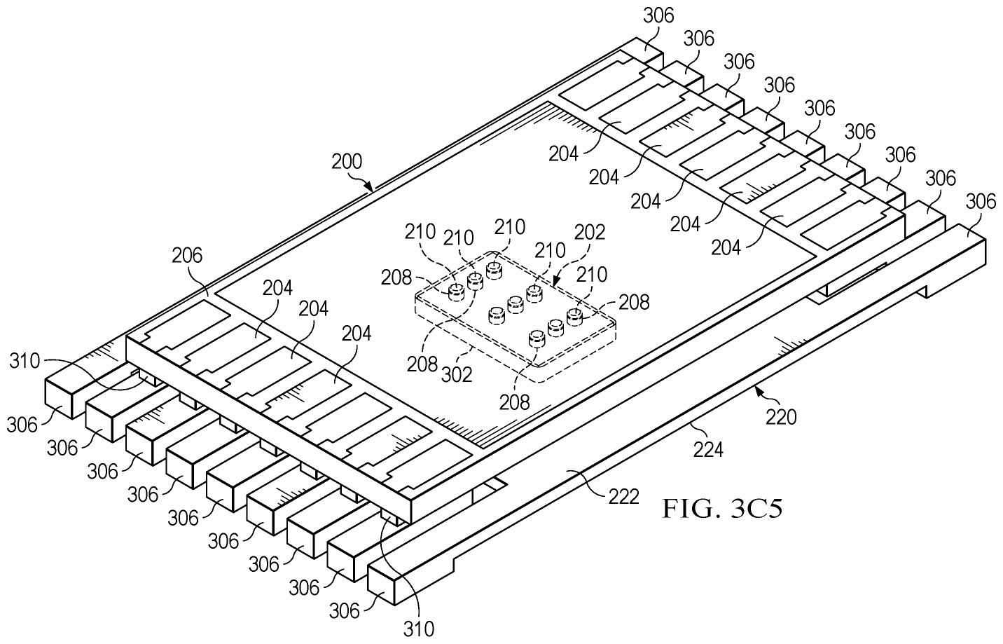

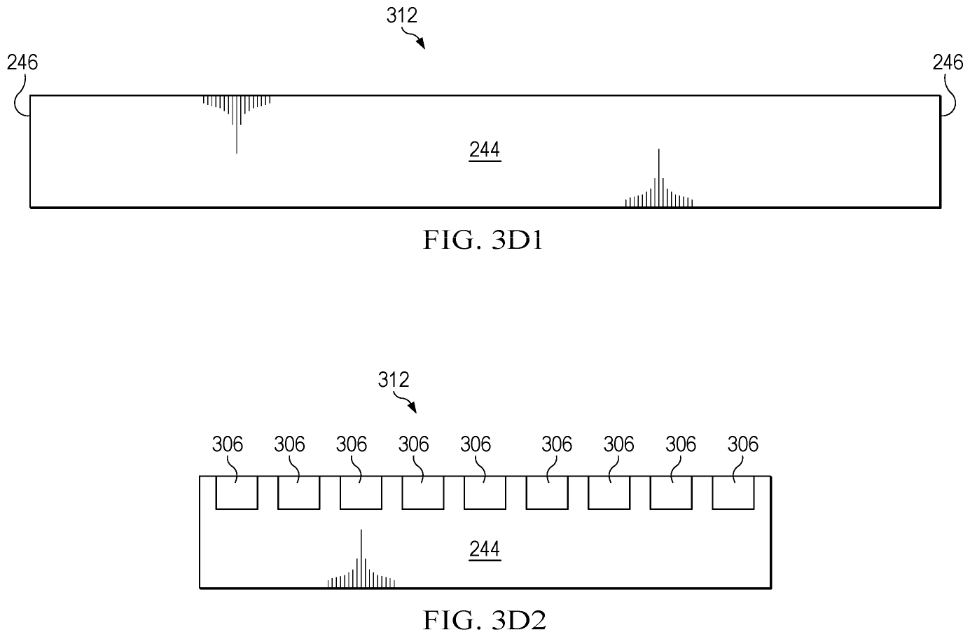

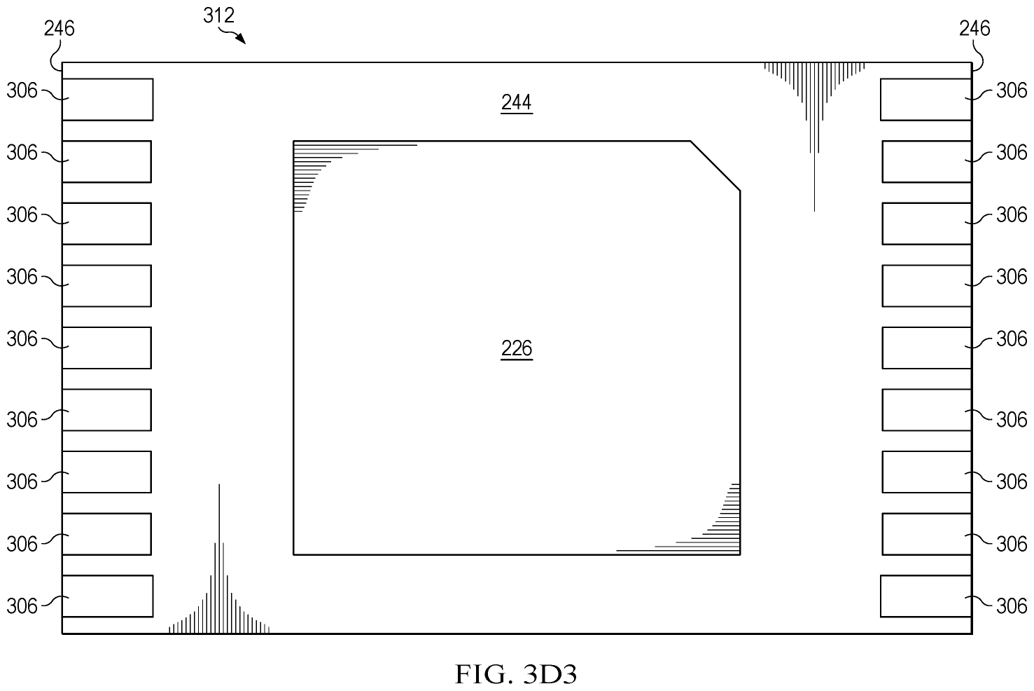

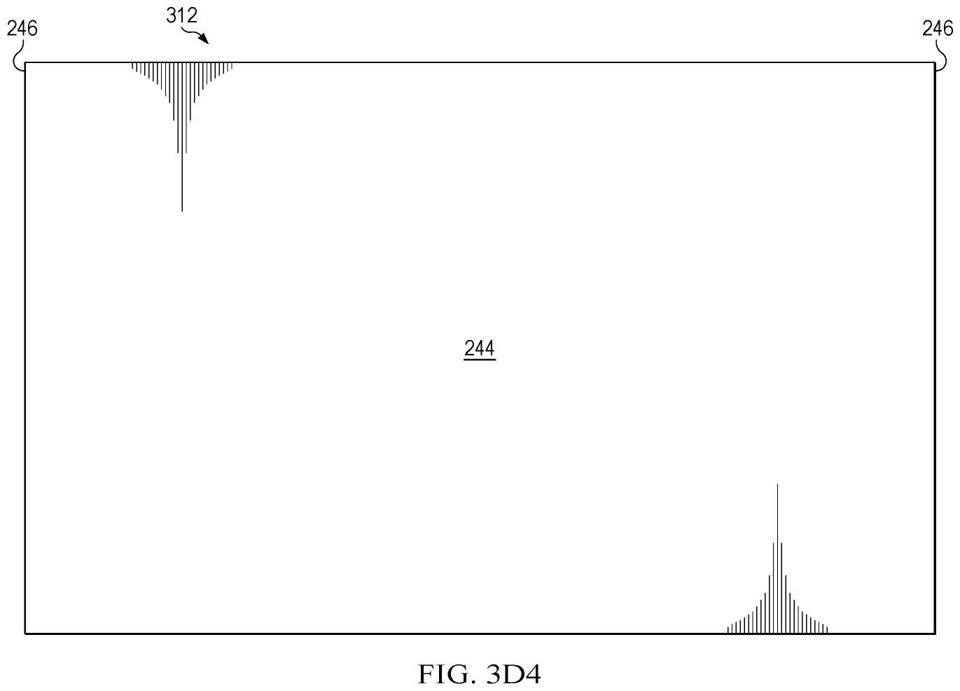

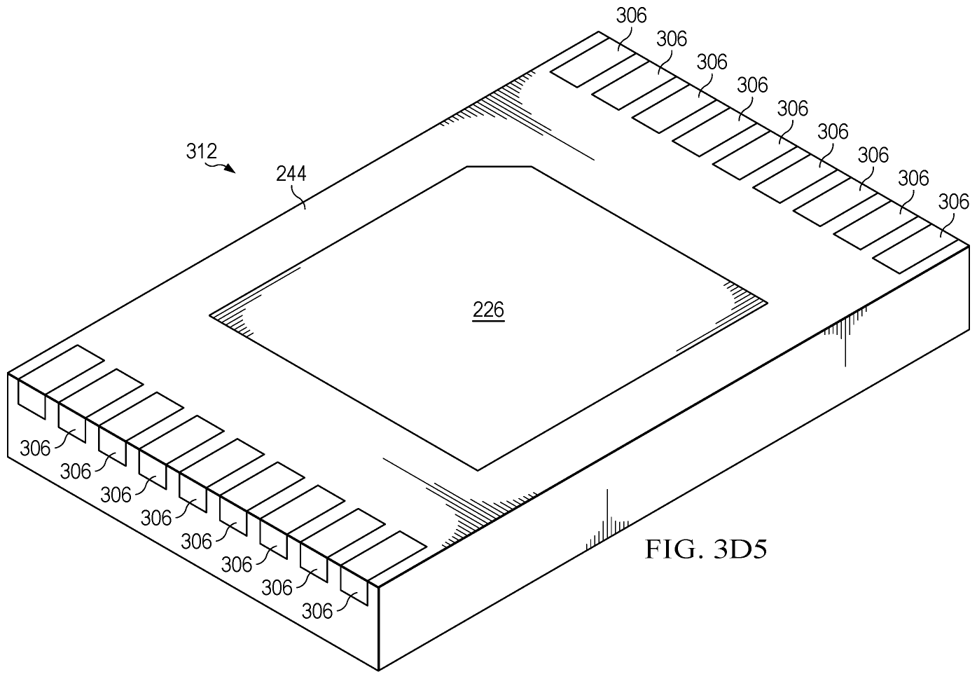

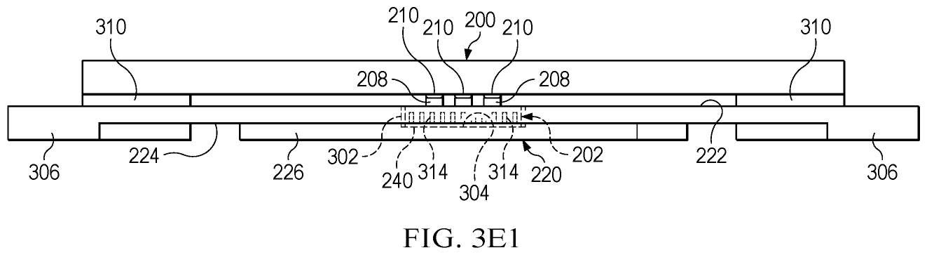

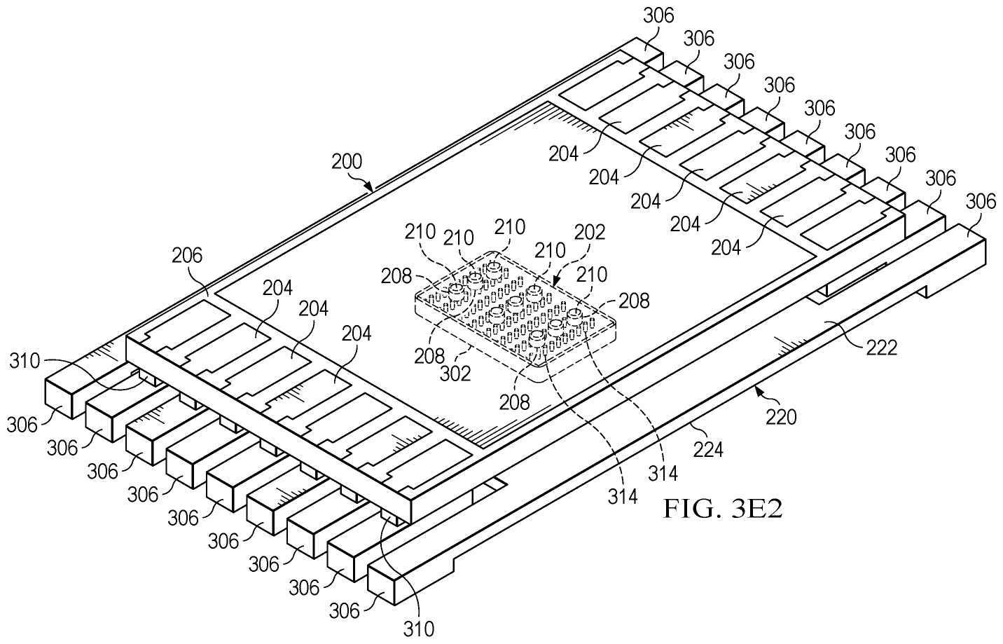

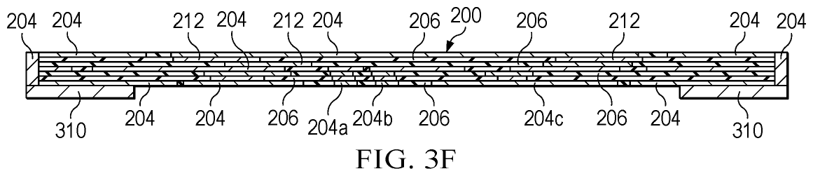

It may be desirable to reduce the thickness of the semiconductor package 248 produced using the techniques described herein. It may also be desirable to position the semiconductor die 202 close to the die pad extension member 226, and more specifically, closer to the bottom surface of the semiconductor package 248, to improve heat dissipation from the semiconductor die 202. Such improvements may be achieved in some examples by forming a cavity in the die pad 220 and positioning the semiconductor die 202 in the cavity. FIGS. 3A1, 3A2, 3A3, 3A4, and 3A5 are profile, alternative profile, top-down, bottom-up, and perspective views, respectively, of a routing structure and a semiconductor die, in accordance with various examples. FIGS. 3B1, 3B2, 3B3, 3B4, and 3B5 are profile, alternative profile, top-down, bottom-up, and perspective views, respectively, of a die pad, die pad extension member, and conductive terminals, in accordance with various examples. FIGS. 3C1, 3C2, 3C3, 3C4, and 3C5 are profile, alternative profile, top-down, bottom-up, and perspective views, respectively, of a routing structure and semiconductor die coupled to a die pad, a die pad extension member, and conductive terminals, in accordance with various examples. FIGS. 3D1, 3D2, 3D3, 3D4, and 3D5 are profile, alternative profile, top-down, bottom-up, and perspective views of a semiconductor package with enhanced heat dissipation and parasitic inductance mitigation, in accordance with various examples. Together, FIGS. 3A1-3D5 provide a process flow for manufacturing a semiconductor package 312 containing such a cavity and, thus, the improvements in package thickness and heat dissipation described above. The process flow of FIGS. 3A1-3D5 is similar or identical to the process flow of FIGS. 2A1-2D5, with a few exceptions as follows. The structure shown in FIGS. 3B1-3B5 is identical to that shown in FIGS. 2B1-2B5, except for the presence of a cavity 302 in the die pad 220, and more specifically, in the surface 222 of the die pad 220. The cavity 302 has a depth that ranges from 50 microns to 100 microns, with a depth greater than this range being disadvantageous because the remaining material thickness below the cavity 302 becomes unacceptably thin and fragile, and with a depth less than this range being disadvantageous because it will require the die to be unacceptably thin and thus vulnerable to damage. The cavity 302 has a floor 304. Further, the structure shown in FIGS. 3B1-3B5 has conductive terminals 306, each of which has a single axial center 308, meaning that the conductive terminals 306 do not have separate segments that are in different vertical planes, as is the case in FIGS. 2B1-2B5. Stated differently, each conductive terminal 306 has a uniform thickness and width along an entirety of a length of the conductive terminal 306. FIGS. 3A1-3A5 are identical to FIGS. 2A1-2A5, except for the presence of metal spacing members 310 on the routing structure 200. When the structure of FIGS. 3A1-3A5 is coupled to the structure of FIGS. 3B1-3B5, as shown in FIGS. 3C1-3C5, the metal spacing members 310 provide adequate clearance for the semiconductor die 202, the metal pillars 208, and the solder bumps 210. Stated another way, a combined thickness of the die pad extension member 226, the die pad 220 below the cavity 302, the semiconductor die 202, the metal pillar 208, and solder bump 210 between the metal pillar 208 and the routing structure 200 is approximately equal to a combined thickness of the conductive terminal 306 and one of the multiple metal spacing members 310. The thickness of the metal spacing member 310 may be increased or decreased to enable appropriate contact between the solder bumps 210 and the routing structure 200, as shown in FIG. 3C1. The completed semiconductor package 312 is shown in FIGS. 3D1-3D5.

The presence of the cavity 302 and the planar structure of the conductive terminals 306 decreases the total thickness of the semiconductor package 312. Further, the positioning of the semiconductor die 202 closer to the die pad extension member 226 (due to the cavity 302) increases heat dissipation. Further still, the presence of the cavity 302 reduces the weight of the semiconductor package 312 and the materials cost of the semiconductor package 312.

FIGS. 3E1 and 3E2 are profile and perspective views of a routing structure and semiconductor die coupled to a die pad, a die pad extension member, and conductive terminals, in accordance with various examples. More specifically, FIGS. 3E1 and 3E2 depict that the semiconductor die 202 included in the semiconductor package 312 may include through-silicon vias 314 to enhance heat dissipation. The discussion of the through-silicon vias 250 provided above also applies to the through-silicon vias 314, and thus the vias 314 are not described again here.

FIG. 3F is a profile, cross-sectional view of the routing structure 200 in accordance with various examples. The routing structure 200 of FIG. 3F is identical to that of FIG. 2F, except that the routing structure 200 of FIG. 3F includes metal spacing members 310, as shown. The description provided above of the routing structure 200 in FIG. 2F and the manufacture thereof also applies to the routing structure 200 shown in FIG. 3F, and thus is not repeated here. The metal spacing members 310 may be applied by any suitable technique, such as a plating process (e.g., a plating process performed after the remainder of the routing structure 200 is manufactured).

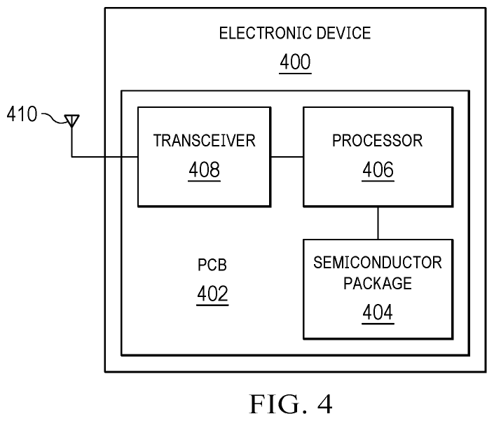

FIG. 4 is a block diagram of an electronic device comprising a semiconductor package with enhanced heat dissipation and parasitic inductance mitigation, in accordance with various examples. Specifically, FIG. 4 shows an electronic device 400 comprising a printed circuit board (PCB) 402. A semiconductor package 404, such as the semiconductor package 248 or the semiconductor package 312, is coupled to the PCB 402. A processor 406 and a transceiver 408 are coupled to the PCB 402. The processor 406 is coupled to the semiconductor package 404 and the transceiver 408. An antenna 410 is coupled to the transceiver 408. The electronic device 400 thus may be an RF device capable of operating in any radio frequency band. The scope of this disclosure is not limited as such, and the electronic device 400 also may include non-RF devices.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, unless otherwise stated, “about,” “approximately” or “substantially” preceding a parameter means being within +/-10 percent of that parameter. Modifications are possible in the described examples, and other examples are possible within the scope of the claims.

What is claimed is:

1. A semiconductor package, comprising:
a semiconductor die having a device side including circuitry and a non-device side opposite the device side;
a metal pillar coupled to the device side and extending away from the semiconductor die;
a routing structure coupled to the metal pillar, the routing structure including:
first and second metal layers, the first metal layer positioned closer to the device side than the second metal layer and coupled to the second metal layer by way of a via; and
a dielectric covering the first and second metal layers and the via;
a die pad coupled to the non-device side of the semiconductor die by way of a thermally conductive material;
a die pad extension member coupled to an opposite surface of the die pad than the semiconductor die;
a conductive terminal having a first horizontal member and a second horizontal member coupled to and vertically offset from the first horizontal member, the second horizontal member soldered to the first metal layer of the routing structure; and
a mold compound covering the semiconductor die, the metal pillar, the routing structure, the die pad, and the conductive terminal, the first horizontal member and the die pad exposed to an exterior surface of the mold compound.

2. The package of claim 1, wherein the semiconductor die includes a through-silicon via in contact with the thermally conductive material and at least partially extending through a thickness of the semiconductor die.

3. The package of claim 1, wherein the thermally conductive material is solder or silver epoxy.

4. The package of claim 1, wherein the routing structure is not a printed circuit board (PCB).

5. The package of claim 1, wherein the dielectric includes AJINOMOTO® Build-Up Film (ABF).

6. The package of claim 1, wherein the second horizontal member of the conductive terminal is closer to the routing structure than is a surface of the die pad to which the semiconductor die is coupled.

7. The package of claim 1, wherein the semiconductor die has a thickness ranging between 50 microns and 250 microns and the die pad has a thickness ranging between 50 microns and 500 microns.

8. The package of claim 1, wherein a combined thickness of the die pad and the die pad extension member is approximately equivalent to a thickness of the first horizontal member.

9. A semiconductor device, comprising:
a semiconductor die having a device side including circuitry and a non-device side opposite the device side;
a metal pillar coupled to the device side and extending away from the semiconductor die;
a routing structure coupled to the metal pillar, the routing structure including:
first and second metal layers, the first metal layer positioned closer to the device side than the second metal layer and coupled to the second metal layer by way of a via; and
a dielectric covering the first and second metal layers and the via;
a die pad having a cavity formed therein, the semiconductor die positioned at least partially inside the cavity, the non-device side of the semiconductor die coupled to a floor of the cavity by way of a thermally conductive material;
a die pad extension member coupled to an opposite surface than the semiconductor die;
a conductive terminal coupled to the first metal layer of the routing structure; and
a mold compound covering the semiconductor die, the metal pillar, the routing structure, the die pad, and the conductive terminal, the conductive terminal and the die pad exposed to an exterior surface of the mold compound.

10. The device of claim 9, wherein the semiconductor die includes a through-silicon via in contact with the thermally conductive material and at least partially extending through a thickness of the semiconductor die.

11. The device of claim 9, wherein the thermally conductive material is solder or silver epoxy.

12. The device of claim 9, wherein the routing structure is not a printed circuit board (PCB).

13. The device of claim 9, wherein the dielectric includes AJINOMOTO® Build-Up Film (ABF).

14. The device of claim 9, wherein the semiconductor die has a thickness ranging between 50 microns and 250 microns and the die pad has a thickness ranging between 50 microns and 500 microns.

15. The device of claim 9, wherein the conductive terminal has a uniform thickness and width along an entirety of a length of the conductive terminal.

16. The device of claim 9, further comprising multiple metal spacing members on a surface of the routing structure facing the semiconductor die.

17. The device of claim 16, wherein a combined thickness of the die pad extension member, the die pad below the cavity, the semiconductor die, the metal pillar, and solder between the pillar and the routing structure is approximately equal to a combined thickness of the conductive terminal and one of the multiple metal spacing members.

18. The device of claim 16, wherein the multiple metal spacing members are coupled to the first metal layer of the routing structure.

19. The device of claim 9, wherein the device is a radio-frequency electronic device and the semiconductor die is a gallium nitride semiconductor die, and wherein the device includes a printed circuit board (PCB) to which the conductive terminal is coupled.

20. The device of claim 9, wherein the routing structure lacks air between the first and second metal layers.

21. A method for manufacturing a package, comprising:
coupling a metal pillar extending from a device side of a semiconductor die to a routing structure, the device side having circuitry formed therein, the routing structure comprising:
first and second metal layers, the first metal layer positioned closer to the device side than the second metal layer and coupled to the second metal layer by way of a via; and
a dielectric covering the first and second metal layers and the via;
coupling a non-device side of the semiconductor die opposing the device side of the semiconductor die to a die pad by a thermally conductive material;
coupling a conductive terminal to the routing structure; and
covering the semiconductor die, the die pad, the metal pillar, the routing structure, and the conductive terminal with a mold compound, the conductive terminal exposed to an exterior surface of the mold compound.

22. The method of claim 21, wherein the surface of the die pad is a floor of a cavity in the die pad.

23. The method of claim 21, wherein the semiconductor die has a thickness ranging from 50 microns and 250 microns.

24. The method of claim 21, wherein the semiconductor die includes a through-silicon via at least partially extending through a thickness of the semiconductor die.

25. The method of claim 21, further comprising a die pad extension member coupled to the die pad and extending away from the semiconductor die, wherein a combined thickness of the die pad and the die pad extension member is approximately equivalent to a thickness of a segment of the conductive terminal.
